(19) United States
(12) Patent Application Publication
(10) Pub. No.: US 2026/0344067 A1
(43) Pub. Date: Oct. 29, 2026

(54) LARGE AREA SINGLE PHOTON AVALANCHE DIODE FOR AMBIENT LIGHT SENSING

(71) Applicant: STMicroelectronics International N.V., Geneva (CH)

(72) Inventors: Jeffrey M. Raynor, Edinburgh (GB); Isobel Nicholson, Edinburgh (GB)

(21) Appl. No.: 19/191,243

(22) Filed: Apr. 28, 2025

(51) Int. Cl. H10F 30/225; H10F 77/40; H10K 59/60

(52) U.S. Cl. CPC H10F 30/225; H10F 77/407; H10K 59/60

(57) ABSTRACT

According to an embodiment, a photosensitive device includes a substrate, a lightly doped epitaxial layer formed on the substrate, and a single photon avalanche diode (SPAD) structure formed in the epitaxial layer. The SPAD structure includes a cathode region formed by an N-well, an anode region surrounding at least a portion of the cathode region, and an avalanche region formed at a junction between the cathode region and the epitaxial layer. The SPAD structure has a diode width between 3 microns and 10 microns and is positioned within a photosensitive area having dimensions between 20 microns and 60 microns. The photosensitive area collects photogenerated charge carriers that randomly diffuse to the avalanche region to trigger an avalanche event rather than using a drift field for fast collection.

### TECHNICAL FIELD

The present disclosure generally relates to electronic devices and, in particular embodiments, to a large area single photon avalanche diode for ambient light sensing.

### BACKGROUND

Ambient Light Sensors (ALS) are widely used in electronic devices such as smartphones, tablets, and other display-equipped devices to measure the color and intensity of ambient lighting conditions. These sensors provide data that helps adjust screen brightness and color temperature to optimize visibility and reduce eye strain for users in varying lighting environments. The information from ambient light sensing systems also contributes to white balance adjustments for images captured by device cameras, ensuring more accurate color reproduction. Modern electronic devices increasingly feature edge-to-edge displays with minimal bezels, which has led to the placement of sensors beneath the display surface, particularly behind Organic Light Emitting Diode (OLED) screens or similar display technologies.

Single Photon Avalanche Diodes (SPADs) represent one approach to photon detection that can operate in low-light conditions. SPADs create an avalanche effect when a photon strikes the device, generating a measurable electrical signal from even a single photon interaction. These devices can be operated in Geiger mode, where they are biased above their breakdown voltage, allowing them to produce a substantial output signal when triggered by a photon. The performance of photosensitive devices can be characterized by several parameters, including dark count rate (DCR), which represents the frequency of false detection events that occur without light and effectively establishes a noise floor for the sensor.

### SUMMARY

Technical advantages are generally achieved by embodiments of this disclosure, which describe a large area single photon avalanche diode for ambient light sensing.

A first aspect relates to a photosensitive device, comprising a substrate; an epitaxial layer formed on the substrate, the epitaxial layer being lightly doped; and a plurality of single photon avalanche diode (SPAD) structures formed in the epitaxial layer, each SPAD structure comprising a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event.

A second aspect relates to a method of detecting light, comprising receiving incident light at a photosensitive device comprising a plurality of single photon avalanche diode (SPAD) structures formed in an epitaxial layer on a substrate, the epitaxial layer being lightly doped, wherein each SPAD structure comprises a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer; collecting photogenerated charge carriers that randomly diffuse through the photosensitive area to the avalanche region over a period of 1 to 50 nanoseconds, inclusive; triggering an avalanche event in response to the photogenerated charge carriers reaching the avalanche region; and detecting the avalanche event as an indication of received light.

A third aspect relates to an electronic device, comprising a display screen; an ambient light sensor positioned beneath the display screen, the ambient light sensor comprising a substrate; an epitaxial layer formed on the substrate, the epitaxial layer being lightly doped; and a plurality of single photon avalanche diode (SPAD) structures formed in the epitaxial layer, each SPAD structure comprising a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event; a non-transitory memory storage comprising instructions; and a processor in communication with the ambient light sensor and the non-transitory memory storage, wherein the processor executes the instructions to receive signals from the ambient light sensor indicating detected ambient light levels, determine display brightness and color temperature adjustments based on the detected ambient light levels, and adjust a brightness and color temperature of the display screen based on the determined adjustments.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIGS. 1A and 1B show a Single Photon Avalanche Diode (SPAD);

FIG. 2 is a top view of a SPAD array arranged in a grid configuration;

FIGS. 3A and 3B illustrate an embodiment of a Single Photon Avalanche Diode (SPAD), shown in a cross-sectional view (FIG. 3A) and a layout view (FIG. 3B);

FIGS. 4A and 4B illustrate an embodiment of a Single Photon Avalanche Diode (SPAD), shown in cross-sectional view (FIG. 4A) and layout view (FIG. 4B);

FIGS. 5A and 5B illustrate an embodiment of a Single Photon Avalanche Diode (SPAD), shown in cross-sectional view (FIG. 5A) and layout view (FIG. 5B);

FIGS. 6A and 6B illustrate an embodiment of a Single Photon Avalanche Diode (SPAD), shown in cross-sectional view (FIG. 6A) and layout view (FIG. 6B);

FIG. 7 is an embodiment SPAD system that incorporates a microlens positioned above a SPAD;

FIG. 8 is an embodiment SPAD system, showing multiple smaller microlenses positioned above a SPAD;

FIG. 9 is a block diagram of an embodiment electronic device implementing the ambient light sensing capabilities described herein;

FIG. 10 is a flowchart of an embodiment method for operating an electronic device according to the embodiments disclosed herein.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of ambient light sensing applications for mobile devices, it should also be appreciated that these inventive aspects may also apply to other photon detection scenarios requiring high sensitivity in low-light conditions. In particular, aspects of this disclosure may similarly apply to biomedical imaging, scientific instrumentation, range-finding systems, optical communications, and security applications where detecting minimal light signals with low noise is beneficial.

Embodiments of the disclosure provide a photosensitive device structure that modifies “Island Photodiodes” into Island Single Photon Avalanche Diodes (SPADs). The device includes a substrate, a lightly doped epitaxial layer formed on the substrate, and a SPAD structure formed in the epitaxial layer. The SPAD structure comprises a cathode region formed by an N-well, an anode region surrounding at least a portion of the cathode region, and an avalanche region formed at the junction between the cathode region and the epitaxial layer.

Unlike conventional SPADs that use an electric “drift” field to quickly collect photocharge in less than a nanosecond, the disclosed structure allows photo-charge to randomly diffuse into the avalanche region. The SPAD structure has a diode width between 3 microns and 10 microns and is positioned within a larger photosensitive area having dimensions between 20 microns and 60 microns. This arrangement creates a disconnect between the optical collection area and the junction/collection area, providing more signal through the larger optical area while maintaining the smaller junction area to keep parasitic effects low.

The photosensitive area surrounding the SPAD structure can collect photogenerated charge carriers that diffuse to the avalanche region and trigger an avalanche event. This approach reduces the dark count rate (DCR) by approximately an order of magnitude compared to conventional designs. The reduction occurs because the number and volume of junctions in a given area (such as 30 μm×30 μm) can be reduced by multiple factors when compared to prior approaches, resulting in correspondingly lower DCR.

Various embodiments may include different configurations with different arrangements of P-well, N-well, and optional deep trench isolation (DTI). Some embodiments include a shallow P-type pinning layer with a depth of 0.1-1.0 μm to reduce surface trap states, decrease recombination, and improve photon detection probability. The large volume of epitaxial material allows for a high percentage (greater than 70%) of photo-generated charge to diffuse to the avalanche region.

The disclosed structure can be particularly advantageous for Ambient Light Sensor (ALS) or proximity sensing applications positioned behind, for example, Organic Light Emitting Diode (OLED) screens, which block more than 90% of ambient light. By reducing DCR while maintaining sensitivity, the structure can advantageously operate with limited light that passes through the screen. Additionally, some embodiments may include microlens arrangements to improve light collection efficiency by refracting light away from non-sensitive regions like DTI and anode areas. These and additional details are further discussed below.

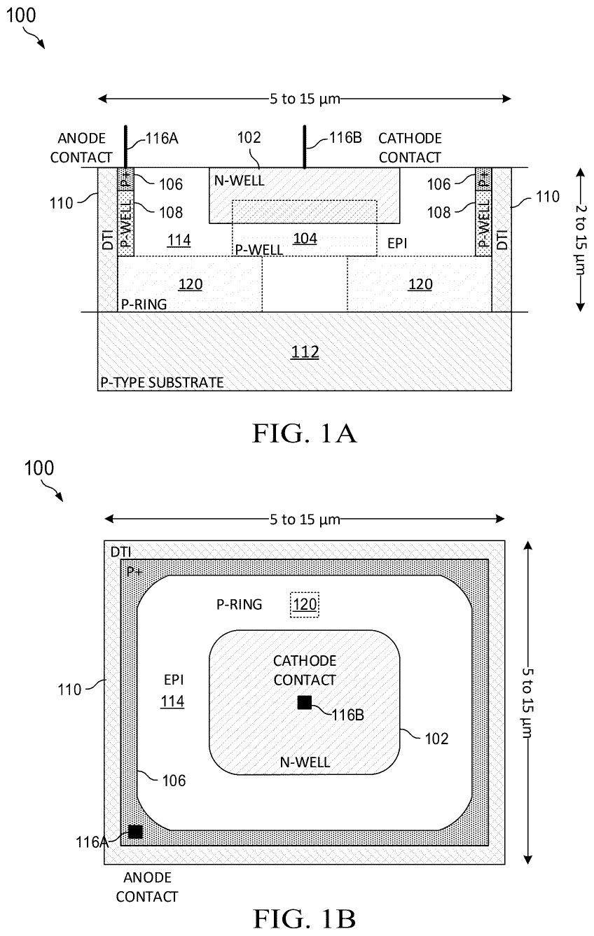

FIGS. 1A and 1B illustrate a Single Photon Avalanche Diode (SPAD) 100. FIG. 1A shows a cross-sectional view, while FIG. 1B depicts a layout view of SPAD 100. The SPAD 100 can operate in Geiger mode, which is biased beyond its breakdown voltage to achieve single-photon sensitivity. When a photon strikes the structure, it generates an electron-hole pair that triggers an avalanche multiplication process, creating a measurable current pulse. This avalanche current is quenched through external circuitry to reset the device to detect subsequent photons. SPAD 100 optimizes the avalanche process while minimizing unwanted noise events, allowing it to detect extremely low light levels, such as those encountered in ambient light sensing applications behind display screens.

SPAD 100 is formed on substrate 112, which serves as the foundation for the device. In embodiments, substrate 112 is a p-type substrate. An epitaxial layer 114 is formed on the substrate 112. This epitaxial layer 114 has a thickness of 2 to 15 microns (not including the substrate), and provides the region where the active components of the SPAD are formed. The epitaxial layer 114 is lightly doped compared to other regions in the structure.

At the center of the structure, an N-well region 102 forms the cathode of the SPAD 100. In embodiments, the N-well region 102 has a doping concentration of 10¹⁹ to 10²⁰ cm⁻³. Directly beneath the N-well region 102 is a P-well region 104. P-well region 104 can have a doping concentration of 10¹⁵ to 10¹⁷ cm⁻³ and extend to a depth of 0.5 to 3 microns.

On either side of the N-well region 102 are heavily doped P+ regions 106. The P+ regions 106 has the highest doping concentration in the structure, typically 10¹⁹ to 10²⁰ cm⁻³, and typically extends to a depth of 0.1 to 0.8 microns. Adjacent to each P+ region 106 is a P-well region 108, which can have similar doping characteristics to the P-well region 104 beneath the N-well region 102. In embodiments, a low resistance path is formed by the implant from the anode.

SPAD 100 includes Deep Trench Isolation (DTI) regions 110 positioned at the outer edges of the structure, as shown in both views. DTI regions 110 provide electrical isolation between adjacent SPAD structures and serve as “Guard Ring” structures to prevent electrons from moving between adjacent photodiodes. The dimension of the SPAD 100 from one DTI region 110 to another is typically between 5 to 15 microns.

Electrical contacts 116 are positioned at the top of SPAD 100, with the anode contact 116A serving as the anode connection to the P+ regions 106 and the cathode contact 116B serving as the cathode connection to the N-well region 102. The electrical contacts allow for the application of bias voltage and the collection of signals generated during avalanche events. The top of the SPAD 100 is the opposite surface to the surface of the epitaxial layer 114 adjacent to the substrate 112.

SPAD 100 may include an optional P-Ring region 120 in the case of a depleted SPAD configuration. This SPAD P-Ring 120 has the lowest doping concentration among the P-type regions in the structure, typically ranging from 10¹⁴ to 10¹⁶ cm⁻³, with a depth of 1 to 5 microns. The P-Ring region 120 surrounds the optional P-well region 104 and extends beneath portions of the N-well region 102. In a depleted SPAD configuration, this lightly doped P-Ring region 120 helps to control the electric field distribution and depletion region formation, improving the uniformity of the avalanche process across the active area. P-Ring region 120 affects the breakdown characteristics and can help reduce edge effects that might otherwise lead to premature breakdown at the periphery of the device. P-Ring region 120 extends laterally within the epitaxial layer 114.

Although FIGS. 1A and 1B illustrate a single SPAD element, additional SPAD elements can be positioned adjacent to SPAD 100 (not shown). The junction between the N-well region 102 and the surrounding P-regions forms the avalanche region where photon detection occurs. The layout view in FIG. 1B shows how the components are arranged in a planar configuration, with the DTI regions 110 forming a boundary around the device's active area.

In Time-of-Flight (ToF) applications, SPAD 100 operates with specific timing requirements to accurately measure distances. When used for ToF measurements, the operational principles of the SPAD focus on the precise timing of the avalanche process.

The ToF operation begins when a photon creates an electron-hole pair at or close to the junction between the N-well region 102 and the surrounding P-regions. Upon generation, the electron is immediately accelerated by the applied electric field created by the high reverse bias voltage. This acceleration provides the electron with sufficient energy to initiate the avalanche process.

As the accelerated electron travels through the silicon lattice, it “collides” with another silicon atom with enough energy to liberate multiple additional electrons. The electric field similarly accelerates the newly freed electrons, creating a cascade effect. This electron multiplication process continues rapidly, resulting in a high current that produces a measurable output pulse at the electrical contacts 116.

For ToF applications, the avalanche and detection process must be extremely fast—typically less than one nanosecond—to provide accurate distance measurements. The speed of the avalanche process is critical because the time between the emission of a light pulse and the detection of its reflection is used to calculate the distance to an object. Even small timing variations can result in significant measurement errors at the high speeds at which light travels.

The operational principles of SPAD 100 can be further understood by examining its circuit behavior and timing characteristics. When operating, SPAD 100 is held in reverse bias beyond its breakdown voltage, creating a metastable state highly sensitive to photon detection. The reverse bias consists of a breakdown voltage component plus an excess voltage component that positions the device in Geiger mode.

When a photon strikes the junction between the N-well region 102 and the surrounding P-regions, impact ionization triggers a chain reaction of electron multiplication. The avalanche occurs extremely rapidly—in approximately 10 picoseconds—and generates a significant current flow between the anode contact 116A and the cathode contact 116B. The avalanche current must be quenched to prevent device damage and reset it for subsequent photon detection.

The quenching process typically employs a quench resistor coupled to the cathode, which limits the current and causes the voltage across the SPAD 100 to drop below the breakdown threshold, stopping the avalanche. Following quenching, a reset period of approximately 10 nanoseconds is required before the SPAD 100 can be biased above breakdown again to detect another photon. During this “dead time,” SPAD 100 is not light-sensitive and cannot detect incoming photons.

SPAD 100 exhibits operational characteristics that distinguish it from conventional photodiodes while sharing certain similarities. SPADs and conventional photodiodes can detect photons, but SPADs like the one depicted in FIGS. 1A and 1B operate with significantly higher sensitivity-capable of detecting even a single photon. The additional sensitivity means that SPADs can generate an output pulse without requiring multiple photons for detection, making them ideal for low-light applications.

In terms of noise characteristics, the SPAD 100 experiences what is termed “Dark count rate” (DCR), which is conceptually analogous to the “Dark Current” in integrating photodiodes. DCR represents the frequency of false detection events that occur in the absence of light due to thermal or tunneling effects within the junction formed between the N-well region 102 and the surrounding P-regions. This parameter effectively establishes a noise floor for the SPAD device.

The detection efficiency of SPAD 100 can be characterized by its Probability of Photon Detection (PDP), which is comparable to the quantum efficiency (QE) parameter used for integrating photodiodes. While quantum efficiency is defined as the ratio of generated electrons to incident photons

$$( i . e . , \frac{N umber of Electrons}{N umber of Photons} ) .$$

the probability of photon detection represents the ratio of detection counts to incident photons

$$( i . e . , \frac{N umber of Counts}{N umber of Photons} ) .$$

It should be appreciated that quantum efficiency can also be applied to SPADs to describe the efficiency with which they convert incident photons into electron-hole pairs that lead to avalanche events. However, in the context of SPADs, it's often referred to as the probability of photon detection to emphasize the detection aspect. The probability of photon detection considers factors like fill factor, avalanche probability, and absorption efficiency.

Another defining characteristic of SPAD 100 is its biasing condition. The device operates with high voltage applied between the electrical contacts 116, creating a high electric field across the junction regions. This high-field condition enables the rapid avalanche process described previously, allowing SPAD 100 to achieve extremely fast response times. The structural arrangement of the N-well region 102, P-well region 104, P+ regions 106, and DTI regions 110 shown in FIGS. 1A and 1B optimizes this high-field operation while controlling unwanted edge effects that could lead to premature breakdown.

Further, SPAD 100 operates with fundamentally different electrical parameters than conventional photodiodes. While standard photodiodes typically operate with a reverse bias voltage of 0-2V, SPAD 100 typically requires a much higher reverse bias voltage in the range of, for example, 12-20V to achieve the necessary conditions for Geiger mode operation. This higher voltage is applied between the electrical contacts 116 to create the strong electric field needed for avalanche multiplication.

The quantum efficiency characteristics of SPAD 100 also differ from conventional photodiodes. While standard photodiodes have quantum efficiency values less than 1 (meaning, on average, fewer than one electron is generated per incident photon), SPADs effectively have a quantum efficiency much greater due to the internal gain provided by the avalanche process. This internal amplification allows a single photon to generate thousands of electrons, resulting in a measurable output signal.

The response speed of SPAD 100 represents another difference from conventional photodiodes. Standard photodiodes typically operate in the microsecond to millisecond range, while SPAD 100 can respond in the picosecond to nanosecond range due to the rapid avalanche process. This speed difference is reflected in the operational domain—conventional photodiodes produce analog outputs (voltage or current) proportional to light intensity. In contrast, SPAD 100 produces digital pulse outputs where the timing of the pulse indicates photon arrival.

The physical dimensions and integration capabilities of SPAD 100 also differ from conventional photodiodes. While standard photodiode pixel size typically ranges in size from 1.1 to 150 microns, the SPAD pixel size has historically been larger (e.g., 25 microns) though technology trends are driving toward smaller dimensions (e.g., 8 microns). The fill factor—the ratio of photosensitive area to total pixel area—is approximately 30% for front-side illuminated (FSI) SPADs without microlenses, comparable to conventional photodiodes without microlenses. However, while conventional photodiodes can achieve nearly 100% fill factor with microlenses, SPADs typically do not incorporate microlenses. For back-side illuminated (BSI) SPADs, fill factors approaching 100% can be achieved without microlenses.

Regarding array implementation, SPAD 100 can be arranged in arrays that differ from conventional photodiode arrays. While photodiode arrays typically use analog multiplexing for readout, SPAD arrays are often arranged in matrices, such as 32×32 elements, particularly when implemented as Silicon Photomultipliers (SiPM).

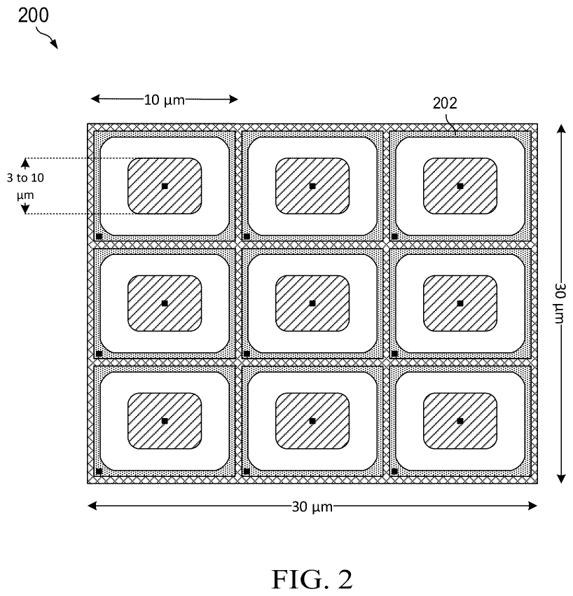

FIG. 2 illustrates a top view of a SPAD array 200 arranged in a grid configuration. As shown, the SPAD array 200 has overall dimensions of 30×30 microns, with each SPAD 202 having a length of 10 microns in the layout view. The diode width can range from 3 to 10 microns within each SPAD 202, representing the active detection region. The SPAD array 200 is surrounded by isolation structures (e.g., the DTI region 110) that separate adjacent SPAD elements and prevent electrical crosstalk. Each SPAD 202 in the SPAD array 200 maintains the same structural configuration as shown in FIGS. 1A and 1B, with cathode contacts positioned at the center of each SPAD element and anode contacts located at the corners of each cell.

The grid arrangement of the SPAD array 200 allows for efficient utilization of the available silicon area while maintaining consistent performance across all detection elements. Each SPAD 202 can function independently, detecting single photons and generating avalanche events as described previously. The spacing between adjacent SPADs 202 is designed to minimize optical and electrical crosstalk while maximizing the fill factor within the constraints of the fabrication process.

This array configuration enables applications requiring spatial detection capabilities, such as low-resolution imaging or multi-point distance measurement in Time-of-Flight systems. The compact 30×30 microns footprint of the entire 3×3 array demonstrates the scalability of the SPAD structure for higher-density integration in sensing applications. When operated as a group, the SPAD array 200 can provide enhanced photon collection capability compared to SPAD 100, improving the detection system's overall sensitivity and signal-to-noise ratio.

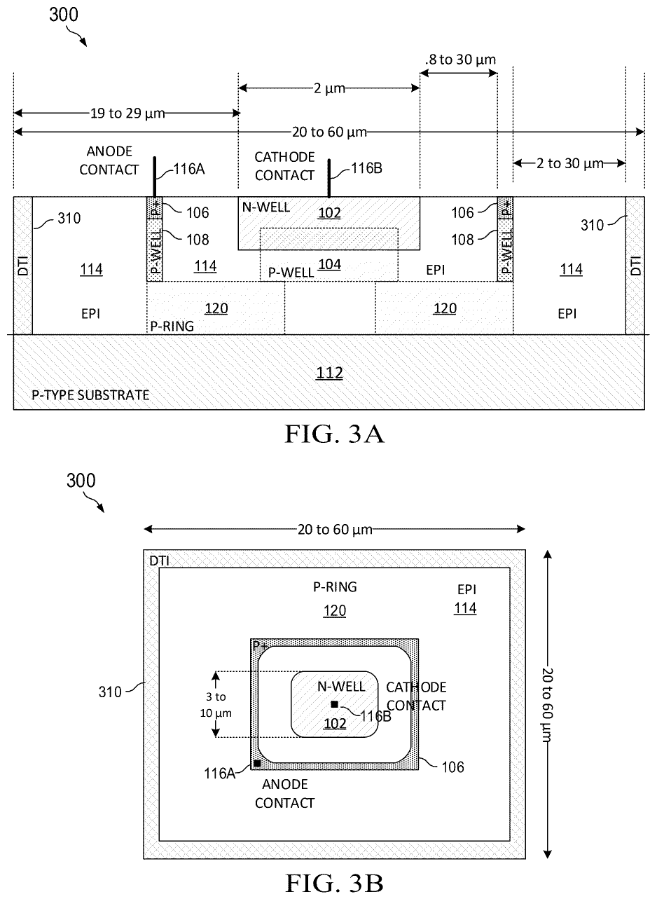

FIGS. 3A and 3B illustrate an embodiment of a Single Photon Avalanche Diode (SPAD) 300, shown in a cross-sectional view (FIG. 3A) and a layout view (FIG. 3B). SPAD 300 represents a modification of the “Island Photodiode” concept into an “Island SPAD” structure. The SPAD 300 shares many structural elements with SPAD 100 shown in FIGS. 1A and 1B, including N-well region 102, optional P-well region 104, P+ regions 106, P-well regions 108, and electrical contacts 116. However, SPAD 300 features a structural difference: the optional Deep Trench Isolation (DTI) region 310 is moved away from the junction, and the intervening space is filled with epitaxial layer 114.

In embodiments, the dimension of SPAD 300 from one DTI region 310 to another ranges between 20 to 60 microns, significantly larger than conventional SPAD structures, such as that shown in FIGS. 1A-B. In some embodiments, this dimension is approximately 30 microns.

In embodiments, the distance from the N-well region 102 to the edge of the SPAD 300 is between 19 and 29 microns. In embodiments, the N-well region 102 has a width between 1 and 4 microns. In an embodiment, the N-well region has a width of 2 microns. In an embodiment, the spacing between the N-well region 102 and each of the P+ regions 106 and P-well regions 108 is between 0.8 and 30 microns. In some embodiments, the spacing between the N-well region 102 and each of the P+ regions 106 and P-well regions 108 is between 0.8 and 20 microns. In an embodiment, the spacing between each of the P+ regions 106 and P-well regions 108 to the DTI region 310 is between 2 and 30 microns. In some embodiments, the spacing between each of the P+ regions 106 and P-well regions 108 to the DTI region 310 is between 2 and 20 microns. In one or more embodiments, the width of each of the P+ regions 106 and P-well regions 108 is between 0.5 and 5 microns.

In embodiments where the DTI regions are optional and, thus, do not provide a clear physical distinction between adjacent SPAD structures' sensitive regions, the 20 to 60 microns dimension refers to the spacing between the diode region of one SPAD structure to the diode region of an adjacent SPAD structure. This spacing may be measured from the edge of one N-well region to the edge of an adjacent N-well region, or alternatively from the center of one N-well region to the center of an adjacent N-well region. This dimensional relationship ensures appropriate spacing for optimal photon collection while minimizing crosstalk between adjacent SPAD structures, even in configurations where physical isolation structures like DTI regions are minimized or absent.

The epitaxial layer 114 has a thickness of 2 to 15 microns (not including the substrate 112). In depleted SPAD embodiments, both the optional P-well region 104 and the P-Ring region 120 can be implemented to control the electric field distribution and depletion characteristics.

In embodiments, the DTI region 310 is optional. Multiple SPADs 300 may share the epitaxial layer 114, with optional separation provided by N-well or Deep-N-well implants rather than DTI regions. This configuration can allow for flexibility in array design while maintaining the operational characteristics of the SPAD structure.

The operation of SPAD 300 for ambient light sensing applications differs significantly from conventional Time-of-Flight (ToF) SPAD operation, as shown in FIGS. 1A-B. In ALS applications, a photon creates an electron-hole pair that may be generated at some distance from the junction. If the photon impinges close to the junction, the operation is similar to that of SPAD 100. However, in most cases, the electron diffuses randomly through the epitaxial material, eventually reaching the junction over a period of 1-50 nanoseconds. Once at the junction, the electron is accelerated by the applied electric field (high reverse bias), acquiring energy and colliding with another silicon atom with enough energy to liberate multiple electrons. This electron multiplication continues, resulting in a high current and output pulse.

SPAD 300 relies on random diffusion of photocharge into the avalanche region in the collection process. In theory, the size of SPAD 300 could be even larger (e.g., up to 60 μm), but this would require a longer path length for the photo-charge to diffuse, increasing the probability of recombination and resulting in signal loss. Based on empirical studies with “island” photodiode structures, a dimension of 20 to 50 microns represents an optimal balance between collection area and recombination losses.

An advantage of the SPAD 300 is the reduction in the number and volume of junctions compared to conventional SPAD designs like the SPAD 100. By utilizing a larger photosensitive area with a smaller junction area, SPAD 300 achieves a significant decrease in junction density. This reduction in junction density directly correlates with improved noise performance. The relationship between junction area and dark count rate is approximately proportional, meaning that reducing the junction area while maintaining the same photosensitive collection area can substantially reduce unwanted noise events. For example, when comparing structures of equivalent total photosensitive area, SPAD 300 can have multiple factors fewer junctions than conventional designs.

In a specific embodiment, if the area of SPAD 100 is 10×10 microns and nine such devices would be needed to cover a 30×30 micron area, SPAD 300 can achieve the same photosensitive coverage with just a single junction. This represents approximately 1/9 the number and volume of junctions compared to the prior art for the same photosensitive area. Consequently, the dark count rate (DCR) of SPAD 300 is reduced by a similar factor—approximately 1/9 of conventional approaches. This significant reduction in DCR improves signal-to-noise performance, especially at lower light levels, making SPAD 300 particularly well-suited for ambient light sensing applications in challenging environments such as behind display screens where very few photons reach the sensor.

SPAD 300 represents a deliberate design choice that would not be advantageous in conventional SPAD applications such as Time-of-Flight (ToF) systems. In ToF applications, timing precision is paramount—the exact arrival time of photons must be measured with sub-nanosecond accuracy to calculate distances correctly. The random diffusion mechanism employed in SPAD 300, which can take 1-50 nanoseconds for photocharge to reach the avalanche region, would introduce unacceptable timing uncertainty in ToF measurements. Further, it should be noted that although the industry trend for conventional SPADs is towards making devices smaller and faster, with considerable effort invested in reducing junction sizes while maintaining timing performance, SPAD 300 takes the opposite approach.

Accordingly, SPAD 300 takes the opposite approach of SPAD 100—deliberately slowing down the collection process by relying on random diffusion rather than drift fields while significantly increasing the ratio of photosensitive area to junction area. This approach is counterintuitive in conventional SPAD applications focusing on speed optimization.

However, this trade-off provides substantial benefits for ambient light sensing applications where timing is not critical but sensitivity in extremely low-light conditions is necessary. The willingness to sacrifice timing precision enables SPAD 300 to achieve superior noise performance through reduced dark count rates, addressing the specific challenges of sensing ambient light through highly attenuating media such as OLED screens, where conventional SPAD structures would be limited by higher dark count rates due to the larger junction areas.

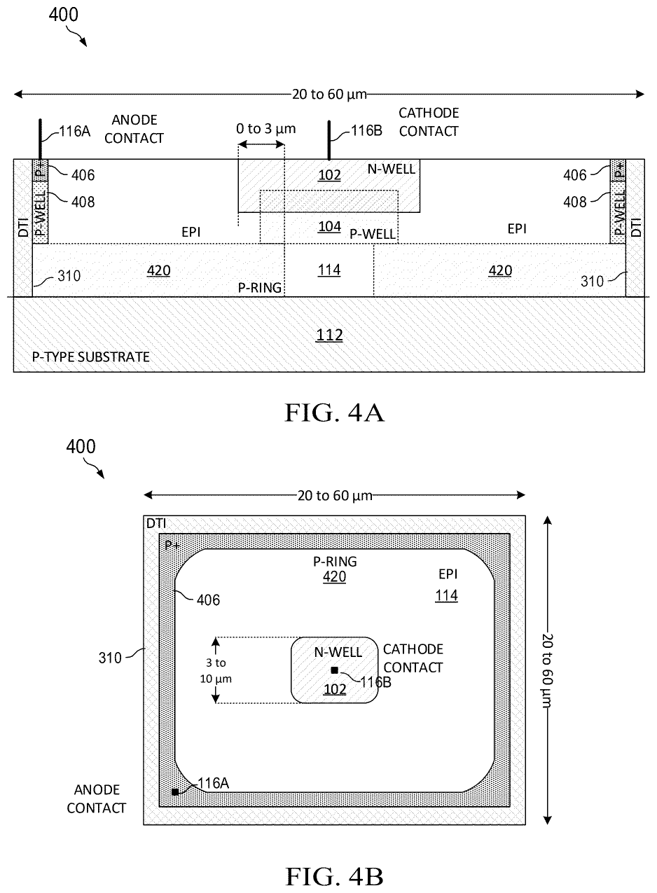

FIGS. 4A and 4B illustrate an embodiment of a Single Photon Avalanche Diode (SPAD) 400, shown in cross-sectional view (FIG. 4A) and layout view (FIG. 4B). SPAD 400 is substantially the same as SPAD 300 shown in FIGS. 3A and 3B regarding operational principles and advantages, but incorporates a modified structural arrangement.

In SPAD 400, the P+ regions 406 and P-well regions 408 are moved away from the junction and positioned adjacent to the Deep Trench Isolation (DTI) region 310. The P+ regions 406 and P-well regions 408 have the same characteristics as P+ regions 106 and P-well regions 108 described previously, with P+ regions 406 typically having the highest doping concentration in the structure (10¹⁹ to 10²⁰ cm⁻³) and extending to a depth of 0.1 to 0.8 microns.

As with SPAD 300, the DTI regions 310 in SPAD 400 are optional. The structure maintains the same overall dimensions. In embodiments, the spacing between DTI regions is approximately 30 microns. The epitaxial layer 114 fills the central region of the structure, providing the medium through which photogenerated carriers can diffuse to reach the avalanche region.

SPAD 400 can also implement the optional P-well region 104 beneath the N-well region 102 and the P-Ring region 420 for depleted implementations. The P-Ring region 420 has the same characteristics as P-Ring region 120 described previously, with a doping concentration typically ranging from 10¹⁴ to 10¹⁶ cm⁻³ and a depth of 1 to 5 microns. In an embodiment, the N-well enclosure of the P-Ring region 420 is 0 to 3 microns, affecting the junction's electric field distribution.

In embodiments, the distance from the N-well region 102 to the edge of the SPAD 300 is between 19 and 30 microns. In an embodiment, the N-well region 102 has a width of 1 to 4 microns, and the spacing between the N-well region 102 and the P+ regions 406 can range from 0.75 to 0.9 microns. This spacing creates a region where the epitaxial layer 114 directly interfaces with the N-well region 102 without the immediate presence of heavily doped P-type regions.

The operational principles of SPAD 400 are similar to those of SPAD 300, relying on random diffusion of photogenerated carriers through the epitaxial layer 114 to reach the avalanche region at the junction between the N-well region 102 and the surrounding material. This configuration maintains the advantages of reduced junction volume and the corresponding reduction in dark count rate while further optimizing the electric field distribution around the junction by relocating the heavily doped P-type regions away from the immediate vicinity of the junction.

As with SPAD 300, SPAD 400 is particularly advantageous for ambient light sensing applications where timing precision is less critical than noise performance and would not be suitable for Time-of-Flight applications requiring sub-nanosecond timing precision. The modified arrangement of the P+ regions 406 and P-well regions 408 in SPAD 400 provides additional design flexibility while maintaining the operational characteristics that enable superior low-light performance in ambient light sensing applications.

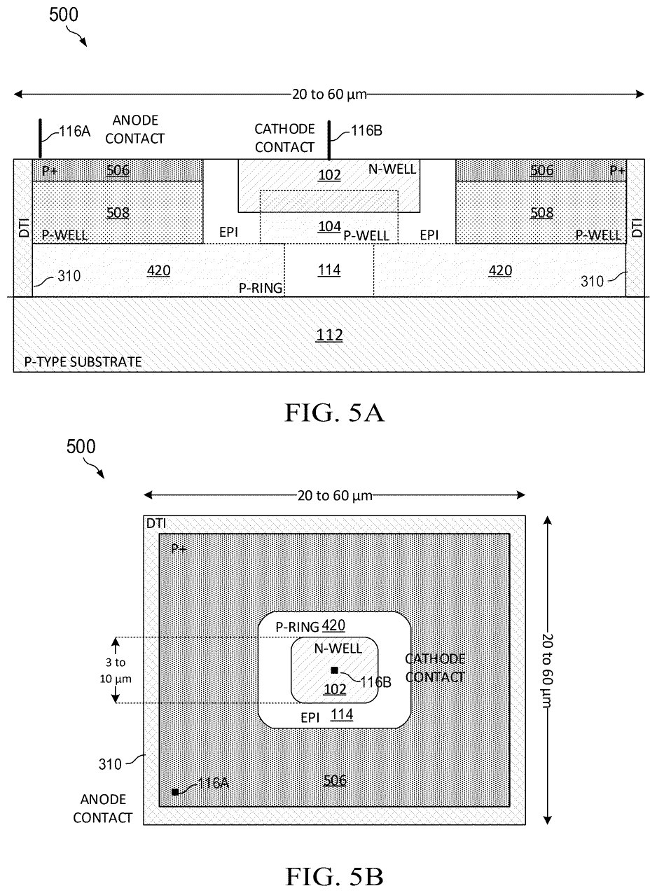

FIGS. 5A and 5B illustrate an embodiment of a Single Photon Avalanche Diode (SPAD) 500, shown in cross-sectional view (FIG. 5A) and layout view (FIG. 5B). SPAD 500 is substantially the same as SPADs 300 and 400 in terms of operational principles and advantages, but it incorporates a further modified structural arrangement. In SPAD 500, the P+ regions 506 and P-well regions 508 are not only positioned adjacent to the Deep Trench Isolation (DTI) region 310 as in SPAD 400, but are also extended to cover a larger area of the structure. For example, in an embodiment where the dimension of SPAD 500 from one DTI region 310 to another is approximately 60 microns, with a diode width of 5 micron, the width of the P+ regions 506 and P-well regions 508 can be approximately 27.5 microns.

The P+ regions 506 and P-well regions 508 have the same characteristics as P+ regions 106 and P-well regions 108 described previously, with P+ regions 506 typically having the highest doping concentration in the structure (10¹⁹ to 10²⁰ cm⁻³) and extending to a depth of 0.1 to 0.8 microns. The P-well regions 508 have doping concentrations similar to the optional P-well region 104.

As with SPADs 300 and 400, the DTI regions 310 in SPAD 500 are optional. The structure maintains the same general dimensions, approximately 20 to 60 microns between DTI regions 310. The epitaxial layer 114 remains in the central region of the structure, though its exposed area is reduced due to the extended coverage of the P+ regions 506 and P-well regions 508.

SPAD 500 can also implement the optional P-well region 104 beneath the N-well region 102 and the P-Ring region 420 for depleted implementations. The P-Ring region 420 has the same characteristics as previously described, with a doping concentration typically ranging from 10¹⁴ to 10¹⁶ cm⁻³ and a depth of 1 to 5 microns.

The N-well region 102 maintains a width of 3 to 10 microns, consistent with the previous embodiments. The extended coverage of the P+ regions 506 and P-well regions 508 creates a different electrical environment around the N-well region 102 compared to SPADs 300 and 400, potentially affecting the field distribution and carrier collection dynamics.

Despite these structural modifications, SPAD 500 operates on the same fundamental principles as SPADs 300 and 400, relying on the random diffusion of photogenerated carriers through the epitaxial layer 114 to reach the avalanche region. The extended P+ and P-well regions may influence the collection efficiency and field distribution. Still, the core advantages of reduced junction volume and the corresponding reduction in dark count rate are maintained.

As with the previous embodiments, SPAD 500 is particularly suited for ambient light sensing applications where timing precision is less critical than noise performance and would not be appropriate for Time-of-Flight applications requiring sub-nanosecond timing precision. The modified arrangement of the P+ regions 506 and P-well regions 508 in SPAD 500 provides another design option within the same fundamental approach of using random diffusion rather than drift fields for carrier collection.

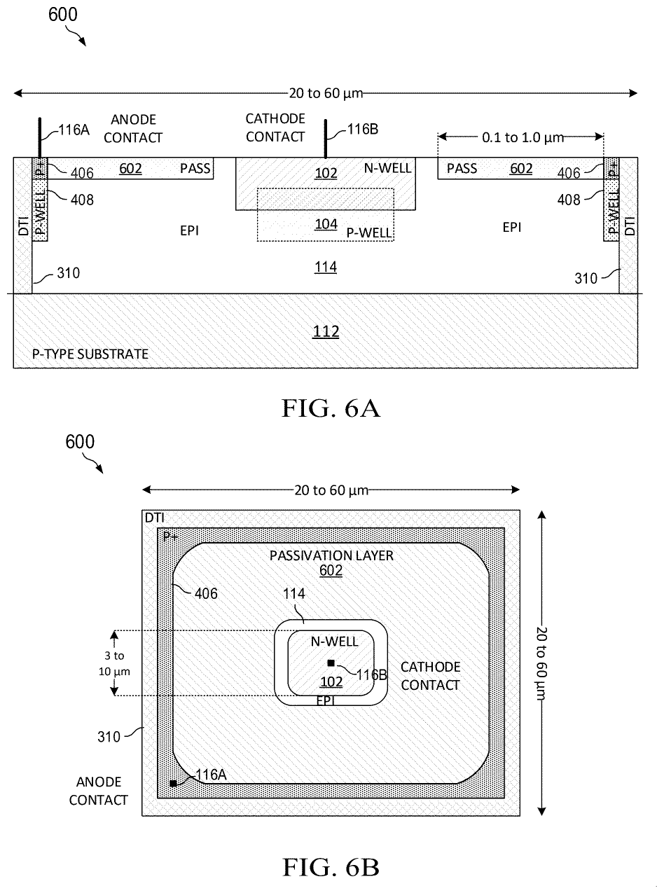

FIGS. 6A and 6B illustrate an embodiment of a Single Photon Avalanche Diode (SPAD) 600, shown in cross-sectional view (FIG. 6A) and layout view (FIG. 6B). SPAD 600 is substantially similar to SPAD 400 in terms of structural arrangement and operational principles but incorporates a passivation layer 602 with a shallow P-type implant. In embodiments, the passivation layer 602 has a depth of 0.1 to 1.0 microns.

The structure maintains the same general components as previous embodiments, including N-well region 102, optional P-well region 104, P+ regions 406, P-well regions 408, epitaxial layer 114, substrate 112, and the Deep Trench Isolation (DTI) region 310. As with previous embodiments, the DTI regions 310 are optional, and the overall dimensions of the structure typically range from 20 to 60 microns between DTI regions.

The passivation layer 602 extends laterally to contact the P+ regions 406 of the anode region, thereby providing a connection to ground. This grounding function ensures that any charge generated at or near the surface—whether by photon interaction or through thermal/mechanical means—is effectively shunted to ground rather than contributing to noise in the detection process. This arrangement advantageously eliminates unwanted “bad electrons” (i.e., charge carriers not created from incident photons), while preserving the device's sensitivity to photons. Since blue light and other higher energy wavelengths tend to be absorbed closer to the surface of the silicon, the thickness of this pinning/passivation layer is kept minimal (preferably less than 0.5 microns) to prevent excessive absorption of these wavelengths before they can generate useful charge carriers in the epitaxial layer. The thinner the pinning layer can be manufactured while maintaining effective passivation, the better the device's sensitivity to the full spectrum of visible light, particularly at the blue end of the spectrum.

The passivation layer 602 extends across a substantial portion of the surface area. The distance from the N-well region 102 to the passivation layer 602 can range from 0 to 4 microns. Preferably, the surface is passivated with a very shallow (less than 0.5 microns) P-type implant. This shallow P-type implant reduces surface trap states at the silicon interface. Surface traps are known to be significant contributors to the recombination of photogenerated carriers, which can reduce the detection efficiency of the device. Passivating the surface with passivation layer 602 reduces the recombination rate, resulting in a higher probability of photon detection (PDP).

Advantageously, the passivation layer 602 is particularly effective because the random diffusion mechanism employed in these SPAD structures means carriers may travel significant distances through the epitaxial material before reaching the avalanche region. Without proper passivation, many of these carriers could recombine at surface trap states before reaching the avalanche region. The large volume of epitaxial layer 114 allows for a high percentage (greater than 70%) of photo-generated charge to successfully diffuse to the avalanche region. The passivation layer 602 effectively preserves more of the photogenerated carriers, allowing them to successfully diffuse to the avalanche region.

As with previous embodiments, SPAD 600 can implement the optional P-well region 104 beneath the N-well region 102 for depleted implementations. The N-well region 102 maintains a width of 3 to 10 microns, consistent with the previous embodiments.

SPAD 600 operates on the same principles as the previous embodiments, relying on random diffusion of photogenerated carriers through the epitaxial layer 114 to reach the avalanche region. The addition of the passivation layer 602 enhances the efficiency of this process by reducing carrier losses while maintaining the core advantages of reduced junction volume and a corresponding reduction in dark count rate.

This embodiment represents an optimization of the Island SPAD concept for ambient light sensing applications, where the combination of low dark count rate and high detection efficiency is particularly valuable for detecting the minimal photons that pass through highly attenuating media such as OLED screens.

Each of the Single Photon Avalanche Diode (SPAD) structures described in the disclosure offers advantages and tradeoffs that make them suitable for different operational requirements. The various SPAD configurations (300, 400, 500, and 600) represent different approaches to optimizing performance characteristics for ambient light sensing applications.

For example, SPAD 300 implements the Island SPAD concept, where the junction area is significantly reduced compared to conventional SPADs while maintaining a large photosensitive collection area. While this structure offers substantial dark count rate (DCR) reduction, it may experience lag due to the potential barrier created at the junction between the N-well region and surrounding P-regions. This lag can result from the time required for photogenerated carriers to overcome this barrier during the random diffusion process. The lag characteristic can make SPAD 300 less suitable for timing-critical applications but acceptable for ambient light sensing where absolute timing precision is not required.

As another example, SPAD 400 represents an optimization where the P+ regions and P-well regions are relocated away from the junction and positioned adjacent to the Deep Trench Isolation regions. This configuration may provide a very effective guard ring structure due to the large gap between the anode and cathode regions. The increased spacing can create a more gradual electric field distribution around the junction, potentially reducing premature breakdown and improving device reliability. This arrangement can enhance the consistency of the avalanche process while maintaining the low dark count rate advantages of the Island SPAD approach. The guard ring effect in SPAD 400 can be particularly valuable for applications requiring stable operation over time and temperature variations.

As yet another example, SPAD 500 features P+ regions and P-well regions that not only are positioned adjacent to the DTI regions but also extend to cover a larger area of the structure. While this configuration maintains the advantages of the Island SPAD concept, it may introduce a risk of tunneling effects due to the high electric field at the surface caused by the proximity of the anode to the cathode. The high field concentration can potentially lead to increased noise through tunneling-induced dark counts, somewhat offsetting the benefits of the reduced junction volume. This tradeoff may be acceptable in applications where other performance characteristics outweigh the potential increase in noise from tunneling effects.

Finally, SPAD 600 incorporates an enhancement by adding a surface passivation layer with a shallow P-type implant. This structure benefits from the surface passivation and the largest volume of epitaxial material among the variants, resulting in lower dark signal and higher photon detection efficiency (PDE). The passivation layer effectively reduces surface trap states, decreasing the recombination of photogenerated carriers and improving overall sensitivity. In embodiments, the SPAD 600 lacks a P-ring connection to the anode, leading to a very high breakdown voltage as the device may break down laterally with tunneling along the surface. This characteristic can be advantageous in applications requiring operation at higher voltages but may require careful management of the gap between the N+ and P+ regions to prevent excessive electric field concentration.

The effectiveness of the passivation approach in SPAD 600 can be particularly valuable when the gap between the N+ and the P+ regions is large enough to prevent a high electric field that could induce tunneling effects. The surface passivation can significantly improve carrier lifetime in the epitaxial region, allowing more photogenerated carriers to successfully diffuse to the avalanche region rather than recombining at surface trap states.

Each of these SPAD structures represents a different balance of performance characteristics, with varying tradeoffs in terms of dark count rate, photon detection efficiency, breakdown voltage, and operational stability. The selection of a specific structure can be tailored to the requirements of particular ambient light sensing applications, considering factors such as the expected light levels, power constraints, and reliability requirements.

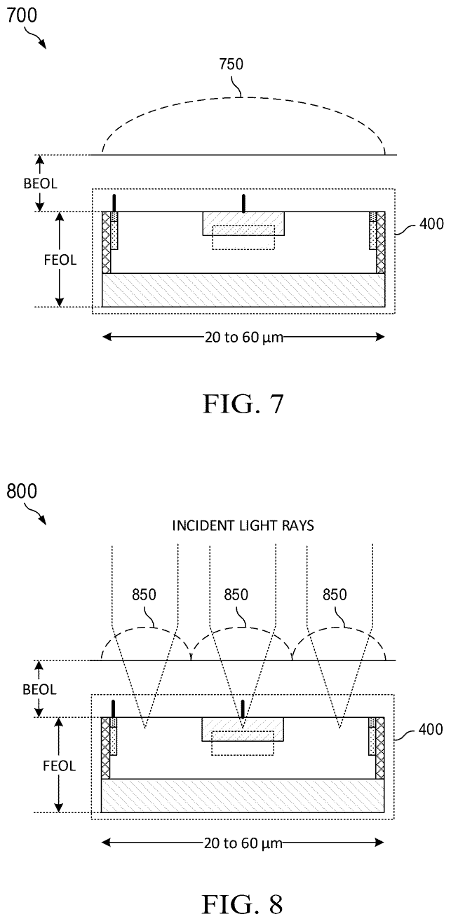

FIG. 7 illustrates an embodiment SPAD system 700 that incorporates a microlens 750 positioned above a SPAD 400. The SPAD 400 maintains the same structural elements and operational principles as described previously, with the addition of Back-End-Of-Line (BEOL) and Front-End-Of-Line (FEOL) regions. In embodiments, the overall width of the structure remains approximately 30 microns.

The microlens 750 is added to improve the probability of photon detection (PDP) by refracting incident light toward the photo-sensitive region of the SPAD. This enhancement addresses a limitation of the basic SPAD structure: the DTI regions are not light sensitive, and the P-well/P+ anode regions are coupled to ground, meaning that photo-charge that diffuses to these regions will not be collected and effectively represents a lost signal. By incorporating the microlens 750, light can be directed away from these non-sensitive regions and concentrated on the photosensitive areas of the device.

The microlens 750 typically has a refractive index of approximately 1.5 and can be formed in a hemispherical shape. Following standard optical principles, the microlens' height is approximately half its diameter. For example, for a SPAD with a size of 30 microns, the microlens height would be approximately 15 microns. This relatively substantial height can present manufacturing challenges, as typical etching processes used in semiconductor fabrication are limited to depths less than 5 microns.

The focusing action of the microlens 750 depends on the difference in refractive index between the two materials (typically air with a refractive index of approximately 1.0 and the resin of the microlens with a refractive index of approximately 1.5). This has practical implications for packaging: if the device is covered in glue, as is common in chip-scale packaging, the refractive index differential may be significantly reduced or eliminated, potentially rendering the microlens non-functional.

Despite these manufacturing and packaging considerations, adding a microlens 750 can enhance the light collection efficiency of the SPAD structure when properly implemented. This improvement in light collection efficiency complements the Island SPAD structure's low dark count rate characteristics, further optimizing the device for ambient light sensing applications in challenging low-light environments.

While FIG. 7 illustrates the microlens 750 integrated with SPAD 400 as an example, it should be understood that this optical enhancement may similarly be applied to any of the previously described SPAD structures, including SPAD 300, SPAD 500, and SPAD 600. The purpose of the microlens—to refract incident light away from non-sensitive regions and toward the photosensitive areas—remains beneficial regardless of the specific structural variations in the underlying SPAD.

Each of these SPAD variants would experience similar improvements in probability of photon detection (PDP) when coupled with an appropriately designed microlens 750, while maintaining their respective advantages regarding dark count rate reduction and carrier collection efficiency. When implementing the microlens enhancement, the manufacturing considerations and packaging limitations would apply equally to all SPAD variants.

FIG. 8 illustrates an embodiment SPAD system 800, showing multiple smaller microlenses 850 positioned above a SPAD 400. This approach addresses the manufacturing challenges associated with the large single microlens shown in FIG. 7. The SPAD 400 maintains the same structural elements and operational principles as described previously, with the Back-End-Of-Line (BEOL) and Front-End-Of-Line (FEOL) regions. In embodiments, the overall width of the structure is approximately 40 microns, where the distance between the left and right microlens focus point is approximately 30 microns.

Rather than using a single large microlens, this configuration employs an array of smaller microlenses 850 arranged in a 3×3 grid (3 horizontal×3 vertical), resulting in 9 individual microlenses covering a single SPAD device. The primary function of these microlenses remains the same as in the single microlens configuration: to refract incident light rays away from the non-sensitive regions, such as the DTI and anode areas, directing the light toward the photosensitive regions of the SPAD.

This multiple microlens approach offers significant manufacturing advantages. Each individual microlens of the microlenses 850 requires a height of only approximately 5 microns, which is considerably more manageable from a fabrication perspective than the 15 microns height required for a single large microlens. This height falls within the typical capabilities of standard etching processes used in semiconductor manufacturing.

The configuration shown in FIG. 8 represents just one possible arrangement, and other multiples of microlenses are possible depending on the specific requirements and manufacturing constraints. It is also worth noting that “gapless” microlenses—where the microlenses touch each other with no space between them—are not mandatory. Some spacing between individual microlenses may be incorporated without significantly compromising the system's optical performance.

Further, the number and arrangement of microlenses 850 is not limited to the 3×3 configuration presented in FIG. 8. The specific number, size, and arrangement of microlenses can be adjusted based on various factors, including the dimensions of the underlying SPAD structure, manufacturing capabilities, optical performance requirements, and specific application needs. For example, configurations such as 2×2, 4×4, or even non-symmetric arrangements like 2×3 or 3×4 may be implemented. Additionally, the shape and curvature of individual microlenses can be optimized to direct light to specific regions of the SPAD.

While FIG. 8 illustrates the multiple microlens configuration with SPAD 400 as an example, it should be understood that this optical enhancement approach may similarly be applied to any of the previously described SPAD structures, including SPAD 300, SPAD 500, and SPAD 600. The fundamental purpose of the multiple microlens array—to refract incident light away from non-sensitive regions while maintaining manufacturing feasibility—provides benefits regardless of the specific structural variations in the underlying SPAD. Each SPAD variant would experience similar improvements in light collection efficiency when coupled with an appropriately designed array of microlenses 850 while maintaining their respective advantages regarding dark count rate reduction and carrier collection efficiency. This multiple microlens approach represents a practical optical enhancement that can be integrated with any Island SPAD structures described in this disclosure.

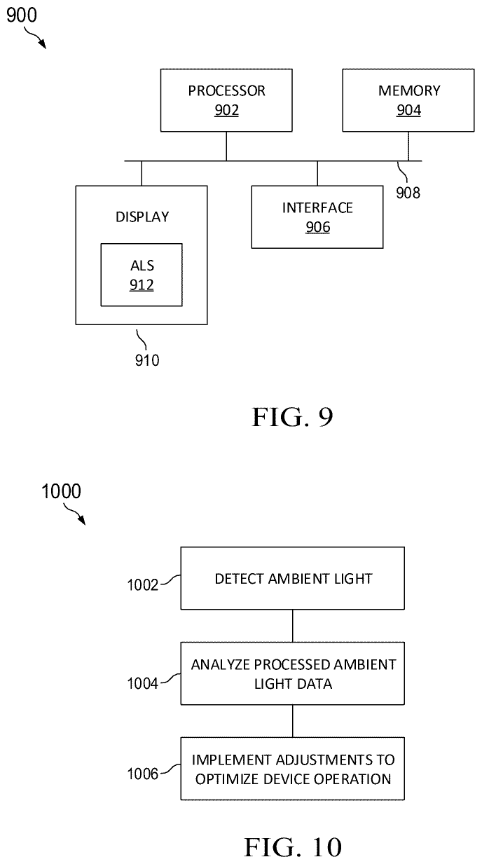

FIG. 9 illustrates a block diagram of an embodiment electronic device 900 implementing the ambient light sensing capabilities described herein. The electronic device 900 includes a processor 902, a memory 904, an interface 906, a bus 908, a display 910, and an ambient light sensor (ALS) 912. The processor 902, memory 904, interface 906, and display 910 are coupled to the bus 908, which facilitates communication between the various components of the electronic device 900.

In embodiments, the ambient light sensor 912 is positioned beneath the display 910. The under-display configuration allows the electronic device 900 to maintain an edge-to-edge display design while capturing ambient light information. Display 910 may be an Organic light-emitting diode (OLED) screen that blocks more than 90% of ambient light, making the high-sensitivity, low-noise characteristics of the SPAD-based ambient light sensor 912 particularly valuable for accurate light detection in this challenging environment.

Processor 902 may comprise various types of processing hardware circuitry capable of executing instructions for operations of the electronic device 900, including processing signals from the ambient light sensor 912. The processor 902 analyzes the ambient light data to determine appropriate display brightness and color temperature adjustments. These adjustments help optimize visibility and reduce eye strain for users in varying lighting environments while contributing to white balance adjustments for images captured by the camera.

The processor 902 can be implemented as a Central Processing Unit (CPU), a Graphics Processing Unit (GPU), a Field-Programmable Gate Array (FPGA), an Application-Specific Integrated Circuit (ASIC), a Digital Signal Processor (DSP), a Neural Processing Unit (NPU), Artificial Intelligence Processing Unit (AIPU) or combinations thereof.

Memory 904 may include non-transitory or transitory memory components that store instructions to be executed by processor 902 for controlling the operations of the electronic device 900, including ambient light sensing and display adjustment functions. When executed by processor 902, these instructions cause electronic device 900 to process signals from the ambient light sensor 912, determine appropriate display adjustments, and implement those adjustments.

In embodiments, memory 904 stores calibration data for the ambient light sensor 912, algorithms for processing ambient light information, and parameters for adjusting display characteristics based on detected ambient light conditions. The memory 904 may additionally store historical ambient light data to enable the processor 902 to identify lighting patterns and optimize display adjustments over time.

Interface 906 facilitates communication with external devices and provides additional connectivity options for the electronic device 900. Interface 906 may include wireless communication capabilities, audio input/output connections, and other peripheral interfaces that enhance the functionality of the electronic device 900.

Display 910 provides the visual output for the electronic device 900 and may incorporate various technologies such as OLED, LCD, or other display types. Display 910 is configured to dynamically adjust its brightness and color temperature based on signals from processor 902, which processes the ambient light information collected by ambient light sensor 912.

Ambient light sensor 912 comprises the plurality of SPAD structures described in previous embodiments, positioned beneath the display 910. The SPAD structures in the ambient light sensor 912 utilize random diffusion of photogenerated charge carriers rather than drift fields, enabling high sensitivity with significantly reduced dark count rates. This configuration is particularly advantageous for detecting the minimal amount of ambient light that passes through the display 910.

Ambient light sensor 912 is configured to continuously or periodically monitor the ambient light conditions through display 910. When lighting conditions change, the SPAD structures detect these changes despite the significant light attenuation caused by the display 910. The processor 902 processes this information to dynamically adjust display brightness and color temperature, ensuring optimal viewing experience across varying environmental conditions while minimizing power consumption. In embodiments, the ambient light information may improve camera performance by providing accurate white balance reference data.

The SPAD structures described in this disclosure can also be implemented in intensity-based proximity sensing applications. In such embodiments, the electronic device 900 may include a photon emitter such as a Light Emitting Diode (LED), Vertical Cavity Surface Emitting Laser (VCSEL), or similar light source positioned near the SPAD-based sensor.

In embodiments, the photon emitter is pulsed on and off at a kilohertz rate, and the SPAD structures take measurements when the emitter is active and when it is inactive. This measurement process may be repeated multiple times to improve the signal-to-noise ratio.

When an object comes into proximity with the electronic device 900, a portion of the emitted light reflects off the object and returns to the SPAD structures. The processor 902 can calculate the difference between measurements taken during emitter-on and emitter-off periods. In embodiments, if this difference exceeds a pre-defined threshold, the processor 902 generates a signal indicating that an object is in close proximity to the device.

In some embodiments, two distinct thresholds are implemented to provide hysteresis in the detection process. This dual-threshold approach can help prevent false proximity indications when an object hovers near the detection threshold, enhancing the reliability of the proximity sensing function.

The low dark count rate and high sensitivity of the SPAD structures described herein make them particularly well-suited for this proximity sensing application, as they can reliably detect the small changes in reflected light intensity that indicate the presence of nearby objects.

FIG. 10 illustrates a flowchart of an embodiment method 1000 for operating the electronic device 900 according to the embodiments disclosed herein. Method 1000 provides an example of how the electronic device 900 utilizes ambient light measurements from the SPAD-based ambient light sensor 912 to optimize device operation. In various embodiments, the method may include additional or fewer steps, or the steps may be performed differently than illustrated.

At step 1002, the electronic device 900 detects ambient light through the display 910 using the SPAD-based ambient light sensor 912. This detection occurs despite the significant attenuation of light (typically greater than 90%) caused by the display 910. With their enhanced sensitivity and reduced dark count rate, the SPAD structures collect photogenerated charge carriers that randomly diffuse to the avalanche regions, triggering avalanche events that are counted as light detection signals. These signals are then processed to determine the ambient light intensity and spectral characteristics.

At step 1004, processor 902 analyzes the processed ambient light data by comparing current readings against predetermined thresholds and historical patterns stored in memory 904. Based on this analysis, the processor 902 determines appropriate adjustments to various device parameters. These determinations may include calculations for optimal display brightness levels, color temperature modifications, and camera white balance settings that enhance user experience and device functionality under the detected lighting conditions.

At step 1006, the electronic device 900 implements the determined adjustments to optimize device operation. In embodiments, the processor 902 sends control signals to adjust the display brightness and color temperature, enhancing visibility and reducing eye strain in the current ambient lighting environment. Additionally, the device may adjust camera settings to improve image capture quality based on the ambient light information. After implementing these adjustments, the process returns to the first step, creating a continuous feedback loop that allows the device to respond dynamically to changing lighting conditions.

A first aspect relates to a photosensitive device, comprising a substrate; an epitaxial layer formed on the substrate, the epitaxial layer being lightly doped; and a plurality of single photon avalanche diode (SPAD) structures formed in the epitaxial layer, each SPAD structure comprising a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event.

In a first implementation form of the photosensitive device, according to the first aspect as such, the cathode region comprises an N-well region formed at a top surface of the epitaxial layer, the top surface being opposite to a bottom surface of the epitaxial layer that interfaces with the substrate.

In a second implementation form of the photosensitive device, according to the first aspect as such or any preceding implementation form of the first aspect, each SPAD structure further comprises deep trench isolation (DTI) regions extending vertically from a top surface of the epitaxial layer into the epitaxial layer and positioned at outer perimeter edges of the photosensitive area, wherein the DTI regions provide electrical isolation between adjacent SPAD structures.

In a third implementation form of the photosensitive device, according to the first aspect as such or any preceding implementation form of the first aspect, the anode region comprises P+ regions having a doping concentration between 1019 and 1020 cm-3, inclusive, and extending to a depth between 0.1 and 0.8 microns, inclusive, from a top surface of the epitaxial layer; and P-well regions laterally adjacent to the P+ regions and extending deeper into the epitaxial layer than the P+ regions, wherein the P-well regions extend to a depth between 0.5 and 3 microns, inclusive, the depth of the P-well regions measured from the deepest extent of the P+ regions into the epitaxial layer, and wherein the P-well regions have a lower doping concentration than the P+ regions.

In a fourth implementation form of the photosensitive device, according to the first aspect as such or any preceding implementation form of the first aspect, the P+ regions and P-well regions are laterally spaced from an outer edge of the cathode region by a distance of between 0.8 and 20 microns, measured parallel to the top surface of the epitaxial layer.

In a fifth implementation form of the photosensitive device, according to the first aspect as such or any preceding implementation form of the first aspect, each SPAD structure further comprises deep trench isolation (DTI) regions extending vertically from a top surface of the epitaxial layer into the epitaxial layer and positioned at outer perimeter edges of the photosensitive area, and the P+ regions and P-well regions are laterally spaced from an outer edge of the DTI regions by a distance between 2 and 30 microns, inclusive, the lateral spacing measured parallel to the top surface of the epitaxial layer.

In a sixth implementation form of the photosensitive device, according to the first aspect as such or any preceding implementation form of the first aspect, the P+ regions and P-well regions have a width between 0.5 and 5 microns, inclusive.

In a seventh implementation form of the photosensitive device, according to the first aspect as such or any preceding implementation form of the first aspect, each SPAD structure further comprises a passivation layer formed over a top surface of the epitaxial layer, the top surface being opposite to a bottom surface of the epitaxial layer that interfaces with the substrate, wherein the passivation layer comprises a shallow P-type implant extending into the epitaxial layer to a depth between 0.1 and 1.0 microns, inclusive, from the top surface, and wherein the passivation layer extends laterally to contact P+ regions of the anode region.

In an eighth implementation form of the photosensitive device, according to the first aspect as such or any preceding implementation form of the first aspect, the cathode region comprises an N-well region formed at a top surface of the epitaxial layer, the top surface being opposite to a bottom surface of the epitaxial layer that interfaces with the substrate, and wherein a lateral distance from an outer edge of the N-well region to an adjacent edge of the passivation layer, measured parallel to the top surface of the epitaxial layer, is between 0 and 4 microns, inclusive.

In a ninth implementation form of the photosensitive device, according to the first aspect as such or any preceding implementation form of the first aspect, the photosensitive device further comprising a microlens positioned above each SPAD structure to refract incident light toward the photosensitive area.

A second aspect relates to a method of detecting light, comprising receiving incident light at a photosensitive device comprising a plurality of single photon avalanche diode (SPAD) structures formed in an epitaxial layer on a substrate, the epitaxial layer being lightly doped, wherein each SPAD structure comprises a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer; collecting photogenerated charge carriers that randomly diffuse through the photosensitive area to the avalanche region over a period of 1 to 50 nanoseconds, inclusive; triggering an avalanche event in response to the photogenerated charge carriers reaching the avalanche region; and detecting the avalanche event as an indication of received light.

In a first implementation form of the method, according to the second aspect as such, the substrate is a P-type substrate, wherein the epitaxial layer is a P-type epitaxial layer with a depth between 2 and 15 microns, inclusive.

In a second implementation form of the method, according to the second aspect as such or any preceding implementation form of the second aspect, the cathode region comprises an N-well region formed at a top surface of the epitaxial layer, and wherein each SPAD structure further comprises a P-well region formed beneath the N-well region and extending horizontally between the N-well region and the epitaxial layer, the P-well region having a doping concentration between 1015 and 1017 cm-3, inclusive, and extending to a depth of 0.5 to 3 microns, inclusive, from a top surface of the epitaxial layer.

In a third implementation form of the method, according to the second aspect as such or any preceding implementation form of the second aspect, each SPAD structure further comprises a P-Ring region formed in the epitaxial layer and surrounding the N-well region, wherein the P-Ring region has a doping concentration between 1014 and 1016 cm-3, inclusive, and extends to a depth between 1 and 5 microns, inclusive, from a top surface of the epitaxial layer, and wherein the P-Ring region extends beneath at least a portion of the N-well region.

In a fourth implementation form of the method, according to the second aspect as such or any preceding implementation form of the second aspect, a lateral extension of the P-Ring region beyond an outer edge of the N-well region is between 0 and 3 microns, inclusive, measured parallel to the top surface of the epitaxial layer.

In a fifth implementation form of the method, according to the second aspect as such or any preceding implementation form of the second aspect, each SPAD structure further comprises deep trench isolation (DTI) regions extending vertically from a top surface of the epitaxial layer into the epitaxial layer and positioned at outer perimeter edges of the photosensitive area, and wherein the P-Ring region is laterally spaced from an outer edge of the DTI regions by a distance between 2 and 30 microns, inclusive, measured parallel to the top surface of the epitaxial layer.

A third aspect relates to an electronic device, comprising a display screen; an ambient light sensor positioned beneath the display screen, the ambient light sensor comprising a substrate; an epitaxial layer formed on the substrate, the epitaxial layer being lightly doped; and a plurality of single photon avalanche diode (SPAD) structures formed in the epitaxial layer, each SPAD structure comprising a cathode region having a lateral dimension of between 3 and 10 microns, inclusive, the lateral dimension of the cathode region measured in a direction parallel to a top surface of the epitaxial layer, an anode region surrounding the cathode region, and an avalanche region formed at a junction between the cathode region and the epitaxial layer, wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event; a non-transitory memory storage comprising instructions; and a processor in communication with the ambient light sensor and the non-transitory memory storage, wherein the processor executes the instructions to receive signals from the ambient light sensor indicating detected ambient light levels, determine display brightness and color temperature adjustments based on the detected ambient light levels, and adjust a brightness and color temperature of the display screen based on the determined adjustments.

In a first implementation form of the electronic device, according to the third aspect as such, the electronic device further comprising a grid of microlenses positioned above the SPAD structure to direct an incident light toward photosensitive regions of the SPAD structure and away from non-sensitive regions.

In a second implementation form of the electronic device, according to the third aspect as such or any preceding implementation form of the third aspect, the display screen is an organic light emitting diode (OLED) screen.

In a third implementation form of the electronic device, according to the third aspect as such or any preceding implementation form of the third aspect, the processor is further configured to store historical ambient light data collected by the ambient light sensor; identify lighting patterns based on the historical ambient light data; and predictively adjust the brightness and the color temperature of the display screen and based on the identified lighting patterns before detected ambient light levels change.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

Unless otherwise specified, the various dimensions, doping concentrations, and other physical characteristics of the layers, regions, and structures described in the disclosure remain consistent from one figure to another for similarly named or functionally equivalent elements. The dimensions and measurements presented throughout the disclosure may vary by approximately 5 to 10 percent from stated values. When dimensions or values are expressed as ranging between two numbers, these ranges include the boundary values themselves. The semiconductor structures described can be fabricated with dimensional variations that accommodate manufacturing tolerances, process limitations, or design considerations while maintaining the functional relationships between components. The relative proportions between elements may remain consistent even as absolute dimensions change within acceptable tolerances. These variations in physical parameters can occur without affecting the fundamental operation of the described semiconductor devices and structures.

What is claimed is:

1. A photosensitive device, comprising:
a substrate;
an epitaxial layer formed on the substrate, the epitaxial layer being lightly doped; and
a plurality of single photon avalanche diode (SPAD) structures formed in the epitaxial layer, each SPAD structure comprising:
a cathode region having a lateral dimension of between 3 and 10 microns, inclusive, the lateral dimension of the cathode region measured in a direction parallel to a top surface of the epitaxial layer,
an anode region surrounding the cathode region, and
an avalanche region formed at a junction between the cathode region and the epitaxial layer,
wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event.

2. The photosensitive device of claim 1, wherein the cathode region comprises an N-well region formed at a top surface of the epitaxial layer, the top surface being opposite to a bottom surface of the epitaxial layer that interfaces with the substrate.

3. The photosensitive device of claim 1, wherein each SPAD structure further comprises deep trench isolation (DTI) regions extending vertically from a top surface of the epitaxial layer into the epitaxial layer and positioned at outer perimeter edges of the photosensitive area, wherein the DTI regions provide electrical isolation between adjacent SPAD structures.

4. The photosensitive device of claim 1, wherein the anode region comprises:
P+ regions having a doping concentration between 10¹⁹ and 10²⁰ cm⁻³, inclusive, and extending to a depth between 0.1 and 0.8 microns, inclusive, from a top surface of the epitaxial layer; and
P-well regions laterally adjacent to the P+ regions and extending deeper into the epitaxial layer than the P+ regions, wherein the P-well regions extend to a depth between 0.5 and 3 microns, inclusive, the depth of the P-well regions measured from a deepest extent of the P+ regions into the epitaxial layer, and wherein the P-well regions have a lower doping concentration than the P+ regions.

5. The photosensitive device of claim 4, wherein the P+ regions and P-well regions are laterally spaced from an outer edge of the cathode region by a distance of between 0.8 and 20 microns, measured parallel to the top surface of the epitaxial layer.

6. The photosensitive device of claim 5,
wherein each SPAD structure further comprises deep trench isolation (DTI) regions extending vertically from a top surface of the epitaxial layer into the epitaxial layer and positioned at outer perimeter edges of the photosensitive area, and
wherein the P+ regions and P-well regions are laterally spaced from an outer edge of the DTI regions by a distance between 2 and 30 microns, inclusive, the lateral spacing measured parallel to the top surface of the epitaxial layer.

7. The photosensitive device of claim 4, wherein the P+ regions and P-well regions have a width between 0.5 and 5 microns, inclusive.

8. The photosensitive device of claim 4,
wherein each SPAD structure further comprises a passivation layer formed over a top surface of the epitaxial layer, the top surface being opposite to a bottom surface of the epitaxial layer that interfaces with the substrate,
wherein the passivation layer comprises a shallow P-type implant extending into the epitaxial layer to a depth between 0.1 and 1.0 microns, inclusive, from the top surface, and
wherein the passivation layer extends laterally to contact P+ regions of the anode region.

9. The photosensitive device of claim 8,
wherein the cathode region comprises an N-well region formed at a top surface of the epitaxial layer, the top surface being opposite to a bottom surface of the epitaxial layer that interfaces with the substrate, and
wherein a lateral distance from an outer edge of the N-well region to an adjacent edge of the passivation layer, measured parallel to the top surface of the epitaxial layer, is between 0 and 4 microns, inclusive.

10. The photosensitive device of claim 1, further comprising a microlens positioned above each SPAD structure to refract incident light toward the photosensitive area.

11. A method of detecting light, comprising:
receiving incident light at a photosensitive device comprising a plurality of single photon avalanche diode (SPAD) structures formed in an epitaxial layer on a substrate, the epitaxial layer being lightly doped, wherein each SPAD structure comprises:
a cathode region having a lateral dimension of between 3 and 10 microns, inclusive, the lateral dimension of the cathode region measured in a direction parallel to a top surface of the epitaxial layer,
an anode region surrounding the cathode region, and
an avalanche region formed at a junction between the cathode region and the epitaxial layer,
wherein each SPAD structure is positioned within a photosensitive area having a lateral dimension between 20 and 60 microns, inclusive, the lateral dimension of the photosensitive area measured in a direction parallel to the top surface of the epitaxial layer;
collecting photogenerated charge carriers that randomly diffuse through the photosensitive area to the avalanche region over a period of 1 to 50 nanoseconds, inclusive;
triggering an avalanche event in response to the photogenerated charge carriers reaching the avalanche region; and
detecting the avalanche event as an indication of received light.

12. The method of claim 11,
wherein the substrate is a P-type substrate,
wherein the epitaxial layer is a P-type epitaxial layer with a depth between 2 and 15 microns, inclusive.

13. The method of claim 11,
wherein the cathode region comprises an N-well region formed at a top surface of the epitaxial layer, and
wherein each SPAD structure further comprises a P-well region formed beneath the N-well region and extending horizontally between the N-well region and the epitaxial layer, the P-well region having a doping concentration between 10¹⁵ and 10¹⁷ cm⁻³, inclusive, and extending to a depth of 0.5 to 3 microns, inclusive, from a top surface of the epitaxial layer.

14. The method of claim 13,
wherein each SPAD structure further comprises a P-Ring region formed in the epitaxial layer and surrounding the N-well region,
wherein the P-Ring region has a doping concentration between 10¹⁴ and 10¹⁶ cm⁻³, inclusive, and extends to a depth between 1 and 5 microns, inclusive, from a top surface of the epitaxial layer, and
wherein the P-Ring region extends beneath at least a portion of the N-well region.

15. The method of claim 14, wherein a lateral extension of the P-Ring region beyond an outer edge of the N-well region is between 0 and 3 microns, inclusive, measured parallel to the top surface of the epitaxial layer.

16. The method of claim 14,
wherein each SPAD structure further comprises deep trench isolation (DTI) regions extending vertically from a top surface of the epitaxial layer into the epitaxial layer and positioned at outer perimeter edges of the photosensitive area, and
wherein the P-Ring region is laterally spaced from an outer edge of the DTI regions by a distance between 2 and 30 microns, inclusive, measured parallel to the top surface of the epitaxial layer.

17. An electronic device, comprising:
a display screen;
an ambient light sensor positioned beneath the display screen, the ambient light sensor comprising:
a substrate;
an epitaxial layer formed on the substrate, the epitaxial layer being lightly doped; and
a plurality of single photon avalanche diode (SPAD) structures formed in the epitaxial layer, each SPAD structure comprising:
a cathode region having a lateral dimension of between 3 and 10 microns, inclusive, the lateral dimension of the cathode region measured in a direction parallel to a top surface of the epitaxial layer,
an anode region surrounding the cathode region, and
an avalanche region formed at a junction between the cathode region and the epitaxial layer,
wherein each SPAD structure is positioned within a photosensitive area having a lateral dimension between 20 and 60 microns, inclusive, the lateral dimension of the photosensitive area measured in a direction parallel to the top surface of the epitaxial layer, the photosensitive area configured to collect photogenerated charge carriers that randomly diffuse to the avalanche region to trigger an avalanche event;
a non-transitory memory storage comprising instructions; and
a processor in communication with the ambient light sensor and the non-transitory memory storage, wherein the processor executes the instructions to:
receive signals from the ambient light sensor indicating detected ambient light levels,
determine display brightness and color temperature adjustments based on the detected ambient light levels, and
adjust a brightness and color temperature of the display screen based on the determined adjustments.

18. The electronic device of claim 17, further comprising a grid of microlenses positioned above the SPAD structure to direct an incident light toward photosensitive regions of the SPAD structure and away from non-sensitive regions.

19. The electronic device of claim 17, wherein the display screen is an organic light emitting diode (OLED) screen.

20. The electronic device of claim 17, wherein the processor is further configured to:
store historical ambient light data collected by the ambient light sensor;
identify lighting patterns based on the historical ambient light data; and
predictively adjust the brightness and the color temperature of the display screen and based on the identified lighting patterns before detected ambient light levels change.
